(19) United States
(12) Patent Application Publication
(10) Pub. No.: US 2026/0249887 A1
(43) Pub. Date: Aug. 27, 2026

(54) REAL-TIME MAP DATA GENERATION

(71) Applicant: Zoox, Inc., Foster City, CA (US)

(72) Inventors: Rasmus Fonseca, Boulder Creek, CA (US); Derek Xiang Ma, San Carlos, CA (US); Arunabh Mishra, Brookline, MA (US); Peter Nguyen, San Francisco, CA (US); Imran Saleemi, Los Altos, CA (US); Oytun Ulutan, Buena Park, CA (US)

(21) Appl. No.: 19/063,267

(22) Filed: Feb. 25, 2025

(51) Int. Cl. B60W 60/00; G06F 30/27

(52) U.S. Cl. CPC B60W 60/00272; B60W 2420/403; B60W 2556/10; G06F 30/27

(57) ABSTRACT

Techniques for determining map data by a vehicle in near real-time are described herein. For example, the techniques may include a vehicle computing device determining view data representing different views of an environment based on sensor data from two or more sensors of the vehicle. A machine learned model can receive the view data and historical data (e.g., a state of a detected object) as input data and generate a map of features proximate the vehicle that include lane information, connections between lanes, road topology, traffic signs, a drivable surface boundary, and/or region information (e.g., a construction zone, occluded region, etc.). The map can be used by a planning component of the vehicle computing device to predict a vehicle trajectory for the vehicle to navigate in the environment.

### BACKGROUND

Systems may rely on data for various purposes including, for example, detecting objects and lane boundaries in an environment. As a non-limiting example, actions for a vehicle to operate in the environment may be predicted based on static map data indicating drivable or non-drivable surfaces. Accuracy of the drivable or non-drivable surfaces in the map data can vary which can effect whether the vehicle reacts to an object in the environment or identifies a drivable surface for navigating. For example, a map representing the environment can vary based on the techniques used to generate the map. Inaccurate maps made by systems reduce accuracy and safety of the subsequent predicted actions for the vehicle.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different figures indicates similar or identical components or features.

FIG. 1 is an illustration of an autonomous vehicle in an example environment, in which an example model determines output data representing a map for use in planning operations.

FIG. 2 illustrates an example block diagram of an example computer architecture for implementing techniques to determine a map based on images having different points of view, as described herein.

FIG. 3A illustrates an example block diagram of a computing device implementing an example component(s) to determine features in an environment for including in a map.

FIG. 3B illustrates another example block diagram of a computing device implementing an example component(s) to determine height information and semantic information associated with a map.

FIG. 3C illustrates an example block diagram of a computing device implementing an example component(s) to determine output data representing a map based on example input data.

FIG. 4 is a block diagram of an example system for implementing the techniques described herein.

FIG. 5 is a flowchart depicting an example process for determining a map using an example component(s) and using the map to control an autonomous vehicle in an environment.

### DETAILED DESCRIPTION

This application describes techniques for determining map data by a vehicle in near real-time. For example, the techniques may include a vehicle computing device determining a map of an environment proximate the vehicle based on sensor data from two or more sensors of the vehicle. A machine learned model can receive input data such as sensor data having different views of the environment or ranges from the vehicle. The input data may also include vehicle information, object tracking data for one or more objects tracked by the vehicle, and/or historical data (e.g., a state of a detected object). The machine learned model can generate a map representing features proximate the vehicle which may include lane information, connections between lanes, road topology, traffic signs, roadway markings, a drivable surface boundary, and/or region information (e.g., a construction zone, occluded region, etc.). The map can be used by a planning component of the vehicle computing device to predict a vehicle trajectory for the vehicle to navigate in the environment. Using the techniques described herein, an autonomous vehicle can determine near real-time map data for consideration during planning operations to quickly and/or preemptively avoid objects, thereby improving safety of the autonomous vehicle.

In some examples, a machine-learned model discussed herein can represent at least a component (e.g., a map component) or portion of a perception component or system of a vehicle, such as an autonomous vehicle, that uses raw or processed sensor data to determine a map usable for controlling operation of the vehicle. For example, map data output by the machine-learned model may be used to determine operations of the autonomous vehicle, such as vehicle movement (e.g., by outputting controls sufficient for a vehicle controller to effectuate steering rack controls, velocity controls), door/aperture control, and/or the like. In various examples, the map data can be used for down-stream processing instead of using static map data that may not accurately represent current features in an environment (e.g., a construction zone, an accident or other obstruction, etc.). Additionally, the machine learned model can determine the map data independent of requiring access to data remote from the vehicle (e.g., off-line). The map data generated by the machine learned model can, for example, enable the vehicle to safely operate in environments without telecommunications coverage and/or in areas for which no map is available.

In some examples, output data from the machine learned model (e.g., a map representing features of an environment or features for updating a map), when used in the context of autonomous vehicles, may be considered during vehicle planning (e.g., modifying vehicle behavior, determine a trajectory, modifying a predicted trajectory, etc.) thereby improving vehicle safety as an autonomous vehicle navigates in the environment by planning a route for the autonomous vehicle based on map data that more accurately represent a real-world environment. In various examples, the machine learned model can predict, as part of the output data, a drivable surface boundary as a polyline(s) in a world coordinate system. In some examples, the machine learned model can generate output data representing one or more features for including or updating in a map.

The techniques (e.g., hardware, software, machines, and/or processes) discussed herein may include a computing device of a vehicle receiving input data such as image data (which, as a non-limiting example may be encoded as a bitmap and may either be from sensors, output from one or more models, or otherwise) and implementing a machine learned model to output a map comprising one or more of a drivable surface, a lane, traffic indicators, a construction zone, of other features of an environment represented in the image data. The map can be generated in near real-time (e.g., at a frequency of 10 Hertz or every 0.1 second, or other frequency) as the vehicle traverses or navigates to a destination in an environment. By using the techniques described herein, map data is available to the vehicle independent of whether the vehicle has access to remote data (e.g., can navigate without receiving map data from a remote source). Further, the real-time map generation techniques can improve vehicle decisions in problematic situations (e.g., improve detection of a drivable surface, output more accurate map data for determining a vehicle trajectory, etc.).

In some examples, the computing device can implement a model (e.g., a map component and/or a perception component) to perform near real-time map generation techniques that generate a map that accurately represents of an environment. For instance, the model can receive image data (e.g., a bitmap, heat map, top-down view, perspective view, elevation view (e.g., a bird's eye view or view from above the vehicle), or the like) and determine output data representing features, regions, entities, etc. in the environment. In some examples, the model may receive image data that is based at least in part on sensor data from a sensor associated with an autonomous vehicle (e.g., a perspective view from an image sensor) and second image data that is based at least in part on sensor data from two or more sensors associated with the autonomous vehicle. The model may also or instead receive data associated with a previous time such as historical data representing an object tracked by the vehicle in the environment and/or static map data representing fixed features of an environment (e.g., from a database of the vehicle). The model can, for example, generate a map to represent the environment faster than typical approaches to enable the vehicle to safely traverse in the environment in near real-time. For example, the map can more accurately represent features in an environment such as static objects, dynamic objects, traffic signs, and include context such as rules of the road, lane directionality, lanes configured temporally that occupy a region not normally driven on (e.g., a sidewalk, a bike lane, etc. due to construction, or other reason). In some examples, objects in a map (e.g., either as input or output of a model) can be represented as raster features, as polylines, and the like. Additional details of determining a polyline to represent a map feature are described in U.S. patent application Ser. No. 17/216,527, filed on May 29, 2021, entitled “Object Trajectory Determination,” which is incorporated herein by reference in its entirety and for all purposes.

Data output by the machine learned model can be used in a variety of ways. An output of the machine learned model can be used during planning operations by an autonomous vehicle traversing in an environment. For example, a planning component can determine a vehicle trajectory based on the map data output by the model that accurately represents object locations, lanes, boundaries, or a drivable surface, to name a few. The map may include polygons that more accurately represent the object locations, etc. thereby improving safety (and passenger comfort) as the vehicle navigates in the environment. Additional details of determining a boundary shape such as a contour or polygon are described in U.S. patent application Ser. No. 17/138,751, filed on Dec. 30, 2020, entitled “Object Contour Determination,” which is incorporated herein by reference in its entirety and for all purposes.

In some examples, the vehicle computing device may provide data such as map data, polygon data, log data, sensor data, etc. to a remote computing device (i.e., computing device separate from vehicle computing device) for data analysis and/or for training a machine learned model. In such examples, the remote computing device may analyze the data to determine accuracy of the map data (or features thereof). Such log data may comprise, for example, sensor data acquired from one or more sensors, derivative data (e.g., perception data determined based on such sensor data), component status messages (e.g., battery state or charge, brake function, etc.), planner and control data, and any other message transmitted while the vehicle is in operation.

As described herein, models may be representative of machine learned models, statistical models, heuristic models, or a combination thereof. That is, a model may refer to a machine learning model that learns from a training dataset to improve accuracy of an output (e.g., a prediction). Additionally or alternatively, a model may refer to a statistical model that is representative of logic and/or mathematical functions that generate approximations which are usable to make predictions.

The techniques discussed herein can improve a functioning of a vehicle computing device in a number of ways. For instance, by accurately and efficiently determining map data as described herein, the vehicle computing device can determine a trajectory or other vehicle action, in less time and with a higher probability to avoid the objects (due to the accuracy of the map (e.g., polygons), parallel techniques, etc.). In some examples, using the map generation techniques described herein, a machine learned model may output representations of features in the environment that improves safe operation of the vehicle by accurately characterizing motion, positions, etc. of the object, drivable surfaces, lane boundaries, etc. with greater detail as compared to previous models. For instance, by implementing multiple viewpoints and types of input data to generate a map in near real-time, a planning component, a prediction component, etc. can determine a vehicle trajectory that can improve passenger comfort and safety. Accordingly, utilizing map data by the vehicle computing device can improve the accuracy and/or reduce a latency for the vehicle to respond to a potential collision in the environment (e.g., does not require a connection to a network to access remote map data).

Furthermore, such techniques may be used, for example, to validate the safe operation of a vehicle. In some examples, the planning component can improve functioning and safety of the vehicle by preventing the vehicle from taking additional actions that are not required (e.g., avoiding sudden braking or swerving when not needed) based on evaluating specific regions, objects, or conditions in the environment around the vehicle represented by the map data.

The techniques discussed herein can also improve a functioning of a vehicle computing device in a number of additional ways. For example, some operations can be performed in parallel to generate the map data in less time thereby enabling downstream predictions that consider the map data to be output in less time and with more accuracy (versus not implementing the techniques). For example, the techniques enable for efficient use of available computational resources (e.g., a memory, a processor, a power supply, etc.) by generating a map of an environment in the least amount of time. The map can, for example, comprise drivable surface boundaries that enable faster generation of a trajectory for consideration by the vehicle. Accordingly, the techniques discussed herein may reduce the amount of computational processing, network bandwidth, and/or power consumption to control an autonomous vehicle (or other robotic device) while simplifying the computational complexity.

The techniques discussed herein can also improve a functioning of a vehicle computing device by determining a position and/or an orientation of the vehicle based on a map data while reducing or eliminating reliance on map data stored or received from a remote entity. The vehicle can implement a localization component to determine the position and/or the orientation based on the near real-time map data independent of requiring a connection to a network external the vehicle. In this way, the techniques enable the vehicle to operate in environments for which there is no network connectivity and therefore no access to remotely stored map data. The techniques also support reducing reliance on a centralized mapping system including storing less data in a remote database and reducing computational costs and monetary costs associated with maintaining the centralized mapping system.

In some cases, utilizing an output by a machine learned model may allow an autonomous vehicle to generate more accurate and/or safer trajectories for an autonomous vehicle to traverse an environment using fewer computational resources. In at least some examples described herein, predicted maps may account for an object position, a lane boundary, drivable surface, etc. in less time and more accurately thereby yielding safer decision-making by the computing device. Further, by considering map data in planning operations, computational load to predict potential interaction between an object and a vehicle is reduced, thereby improving the functioning of the computing device. The techniques discussed herein may improve a functioning of the computing device by increasing available computational resources (e.g., repurposing available computational resources) for predicting potential actions for objects and/or a vehicle in the environment. The techniques described herein provide a technological improvement over existing sensing, object detection, classification, prediction and/or navigation technologies. In addition, the techniques can improve the accuracy with which sensor data can be used to determine objects or other features in an environment, and correctly characterize motion of those objects. These and other improvements to the functioning of the computing device are discussed herein.

The methods, apparatuses, and systems described herein can be implemented in a number of ways. Example implementations are provided below with reference to the following figures. Although discussed in the context of an autonomous vehicle in some examples below, the methods, apparatuses, and systems described herein can be applied to a variety of systems. In one example, machine learned models may be utilized in driver-controlled vehicles in which such a system may provide an indication of whether it is safe to perform various maneuvers. In another example, the methods, apparatuses, and systems can be utilized in an aviation or nautical context. Additionally, or alternatively, the techniques described herein can be used with real data (e.g., captured using sensor(s)), simulated data (e.g., generated by a simulator), or any combination thereof.

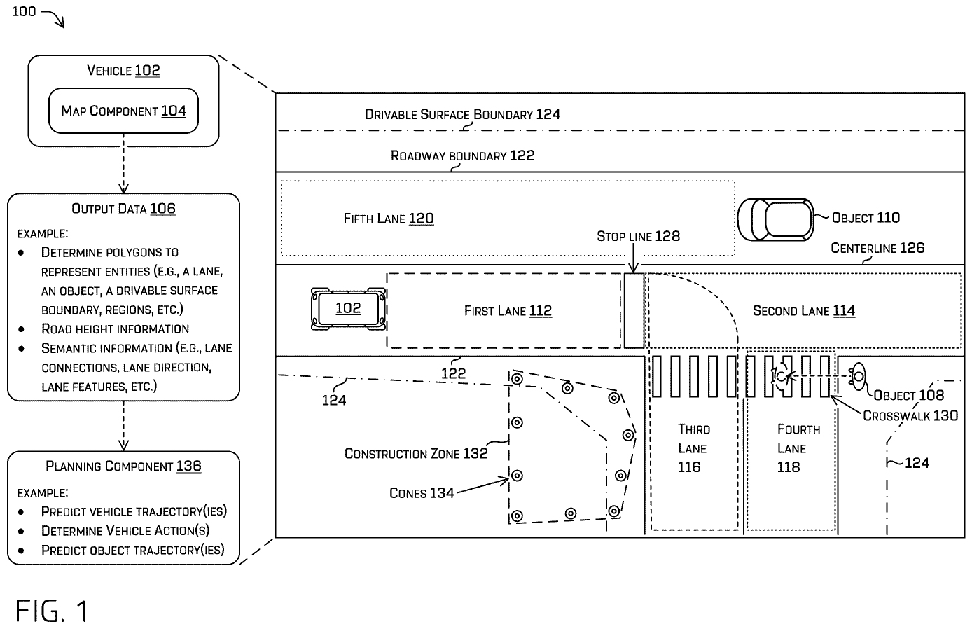

FIG. 1 is an illustration of an autonomous vehicle (vehicle 102) in an example environment 100, in which an example model (map component 104) determines output data representing a map for use in planning operations. For example, the vehicle 102 includes the map component 104 for processing various example input data to determine output data 106 representing a map comprising one or more polygons, height information, road feature information, and/or semantic information. In some examples, the map generating techniques described herein may be implemented at least partially by or in association with a vehicle computing device (e.g., vehicle computing device(s) 404) and/or a remote computing device (e.g., the computing device(s) 434). The environment 100 can represent a simulated environment or a real-world environment, depending on examples.

In some instances, the vehicle 102 may be an autonomous vehicle configured to operate according to a Level 4 or Level 5 classification issued by the U.S. National Highway Traffic Safety Administration, which describes a vehicle capable of performing all safety-critical functions for the entire trip, with the driver (or occupant) not being expected to control the vehicle at any time. However, in other examples, the vehicle 102 may be a fully or partially autonomous vehicle having any other level or classification.

In various examples, the vehicle computing device associated with the vehicle 102 may be configured to detect one or more objects (e.g., object 108 and object 110) in the environment 100, such as via a perception component. In some examples, the vehicle computing device may detect the objects and/or other entities in the environment, based on sensor data received from one or more sensors. In some examples, the sensors may include sensors mounted on the vehicle 102, and include, without limitation, ultrasonic sensors, radar sensors, light detection and ranging (lidar) sensors, image sensors including cameras (e.g. color sensors, monochromatic sensors, RGB-D), infrared sensors, time of flight (ToF) sensors, microphones, inertial sensors (e.g., inertial measurement units, accelerometers, gyros, etc.), global positioning satellite (GPS) sensors, and the like. In various examples, the vehicle 102 may be configured to transmit and/or receive data from other autonomous vehicles and/or other sensors in the environment. The data may include historical data, log data, and/or sensor data associated with the objects detected in the environment 100.

In various examples, the vehicle computing device can receive the sensor data and can semantically classify the detected objects (e.g., determine an object type), such as, for example, whether the object is a pedestrian such as the object 108, a vehicle such as the object 110, a building, a truck, a motorcycle, a moped, or the like. The objects may include static objects (e.g., buildings, bridges, signs, etc.) and dynamic objects such as other vehicles, pedestrians, bicyclists, or the like. In some examples, a classification may include another vehicle (e.g., a car, a pick-up truck, a semi-trailer truck, a tractor, a bus, a train, etc.), a pedestrian, a child, a bicyclist, a skateboarder, an equestrian, an animal, or the like. In various examples, the classification of the object may be used by a model or component to determine object characteristics (e.g., maximum speed, acceleration, maneuverability, candidate positions, etc.). In some examples, potential states, positions, and/or trajectories (also referred to as a candidate trajectory or predicted trajectory herein) by an object may be considered based on characteristics of the object (e.g., how the object may potentially move or operate in the environment).

The vehicle 102 includes the map component 104 that provides functionality to process various types of input data to determine the output data 106 representing a map of the environment 100. The map component 104 can represent one or more models such as a heuristic model, a statistical model, and/or a machine learned model. The map component 104 can determine the output data 106 (e.g., one or more polygons, road height information, semantic information, etc.) to represent entities in the environment 100 such as the object 108 (a pedestrian), the object 110 (another vehicle), lanes (e.g. first lane 112, second lane 114, third lane 116, fourth lane 118, and fifth lane 120), roadway boundaries (e.g., roadway boundary 122), a drivable surface boundary (e.g., drivable surface boundary 124), roadway markings (e.g., a centerline 126, a stop line 128, a crosswalk 130), traffic signals, traffic lights, traffic signs, right-of-way laws, etc. In some examples, the output data 106 can include or identify a construction zone 132 and cones 134.

In various examples, the map component 104 can perform near real-time map generation to accurately represent a real-world environment in which the vehicle 102 traverses. In some examples, the map component 104 can receive image data (e.g., top-down view, perspective view, a bird's eye view, a bitmap, a heat map, or the like) and determine output data representing features, regions, entities, etc. in the environment 100.

In some examples, the map component 104 may receive, as input data, first image data that is based at least in part on first sensor data from a sensor associated with an autonomous vehicle (e.g., a perspective view from an image sensor) and second image data that is based at least in part on second sensor data from two or more sensors associated with the autonomous vehicle. The map component 104 can determine a location or state of the entities using the first image data (e.g., the perspective view having a first range) or the second image data (e.g., the bird's eye view having a second range that is greater than the first range). For example, the map component 104 can determine a portion of the map based on the first image data and another portion of the map based on the second image data.

The input data may also or instead include data associated with a previous time such as historical data representing an object tracked by the vehicle in the environment. For example, the map component 104 can receive perception data representing an object state (e.g., orientation, velocity, acceleration, and/or location, etc.) from a perception component of the vehicle computing device. The perception data can represent information associated with one or more objects sensed a threshold distance from the vehicle. In some examples, the historical data can represent detections at a previous time by the vehicle 102 and/or another vehicle(s) in a fleet of vehicles associated with the vehicle 102.

In some examples, the map component 104 can receive static map data representing fixed features of an environment (e.g., from a database of the vehicle). The map component 104 can receive the static map data from a local and/or remote database. The static map data may be received from a third-party or form a remove computing device (e.g., the computing device(s) 434). The static map data can provide the map component 104 with examples features, lanes, etc. that may or may not be included as an entity in the output data 106. For example, the static map data may provide a machine learned model with examples to include in a map without including the features from the static map data.

As mentioned, the vehicle computing device can receive the sensor data from a sensor coupled to the vehicle or a remote sensor associated with another vehicle or a static location. The sensor data may be processed in various ways to determine features (e.g., state data) associated with the vehicle, an object, and/or the environment. For example, vehicle state data and/or object state data may be determined representing one or more of: a pose, a position, an acceleration, a speed, a size, a type, a lighting state, and the like. The vehicle computing device can also receive previous map data and/or static map data representing the environment from component coupled to the vehicle or remote from the vehicle. By processing the sensor data and the previous map data, the vehicle computing device can determine scene data representing a view of the environment. In some examples, scene data can represent a plan view, a top down view (e.g., a top down representation), an elevation view (e.g., bird's eye view), a perspective view and/or a side view. In some examples, scene data can represent a 360 degree view. In some examples, the view of the environment may represent one or more of: roads, lanes, curbs, shoulders, crosswalks, buildings, trees, medians, street signs, traffic signals, speed limits, and the like. In various examples, the view of the environment can be associated with two or more dimensions.

The output data 106 can include polygons to represent entities such as a lane (e.g., the first lane 112, etc.), an object (e.g., the object 108, the object 110, etc.), a drivable surface boundary (e.g., the drivable surface boundary 124), a region (e.g., the construction zone 132), etc. In various examples, the vehicle 102 can traverse the environment and capture sensor data associated with one or more sensors for use as at least some of the input data. In some examples, the map component 104 can receive a perspective representation, a bird's eye view representation, a top-down representation of the environment, or the like based on the sensor data, and generate the output data 106. For example, the map component 104 can process input data associated with different views, ranges, etc. and determine polygons to represent lane information, a roadway boundary, an object, and other entities in the environment 100.

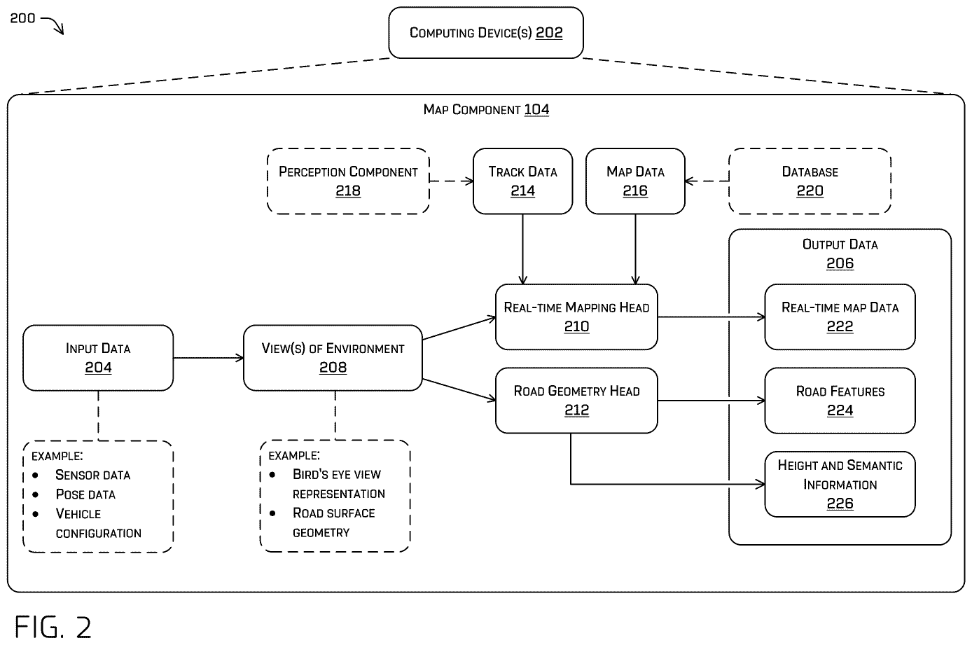

The map component 104 can, for example, generate a map to represent the environment 100 to enable the vehicle 102 to safely traverse in the environment in near real-time. For example, the map represented by the output data 106 can more accurately represent entities in the environment such as static objects, dynamic objects, traffic signs, and include context such as rules of the road, lane directionality, lanes configured temporally that occupy a region not normally driven on (e.g., a sidewalk, a bike lane, etc. due to construction, or other reason). Additional details of an example map component are discussed throughout this disclosure including in FIG. 2 below.

In some examples, the map component 104 can implement or otherwise represent a machine learned model that is configured to generate the output data 106 to include features associated with a map. For example, the machine learned model can output features for including in a new map and/or for updating an existing map. In various examples, the features can represent entities in the environment 100 such as an object, roadway marking, a cone, a lane, etc. In various examples, the map component 104 can determine which features to include in a map that can be generated and/or updated at a later time.

The output data 106 can include height information and/or semantic information for the environment 100. In some examples, the map component 104 can output road height data indicating a topology for one or more roadways proximate the vehicle 102. Additionally, or alternatively, the map component 104 can determine semantic information about the environment 100 such as lane connections, lane directionality, lane features, etc.). An example lane connection can include an indication that the first lane 112 is connected to the second lane 114 (e.g., for navigation) and not connected to the fifth lane 120. The output data can indicate lane direction, lane features such as a bike lane, multiple passenger lane, etc. In some examples, the map can include a semantic description of an original intent for the lane (e.g., a bike lane) and/or a current intent (e.g., a lane for vehicles based on the construction zone 132 causing the bike lane to be used for vehicles).

In various examples, the map component 104 can determine the output data 106 for different times in the future (e.g., every 0.1 second for four second, or some other time period or frequency as the vehicle 102 traverses the environment) representing a map comprising one or more of a drivable surface, a lane, traffic indicators, a construction zone, of other features of the environment 100 over time. In various examples, the map component 104 can iteratively determine the output data 106 for one or more future times based at least in part on the output data 106 associated with a previous time. In other words, the map component 104 can predict map information for different times in the future (such as when the vehicle traverses the environment) with later times considering previous maps, polygons, or potential actions by an object at a previous time.

As mentioned, the map component 104 can determine presence of the construction zone 132, the cones 134, and include the construction zone as part of the output data 106. For example, the vehicle computing device can detect the construction zone 132 which can include or otherwise be defined by cones 134 (or other construction features, traffic indicators, and so on). In some examples, the construction zone 132 can be associated with or included in a top-down view, bird's eye view, perspective view, or other image view point. A model or component of the vehicle computing device (e.g., a machine learned model) can detect the construction zone 132, and the map component 104 can determine a polygon to represent the construction zone 132 based at least in part on receiving image data as input. However, in other examples the map component 104 can generate the map without using a model or component dedicated to detecting a construction zone. Using the techniques described herein can enable the vehicle 102 to more accurately and efficiently avoid or otherwise navigate in the environment 100 relative to the construction zone 132 based on the map component 104 outputting polygon information for the construction zone 132, a drivable surface boundary, etc. Additional details for detecting a construction zone are described in U.S. patent application Ser. No. 17/931,652, filed on Sep. 13, 2022, entitled “Systems and Methods for Construction Zone Detection,” which is incorporated herein by reference in its entirety.

In some examples, the map component 104 can determine the output data 106 based on receiving one or more heat maps as input data. The heat maps can represent various features of the of the environment including objects and may vary in size and/or shape based on historical data indicating a heading, velocity, etc. of a respective object. For example, a same or different model or component can represent a heat renderer that determines a size and/or a shape (e.g., a boundary) of a heat map based at least in part on sensor data, map data, historical data, and so on. In examples when an object is moving in the environment 100 at a first time, a size of the heat map can change (e.g., increase in size when the object speeds up at a second time or decrease in size when the object slows down at a second time). Example heat map data can include a heat map which represents an area the passive object can occupy at a future time, or a heat map that includes multiple cells to represent a likelihood that the passive object will occupy specific areas within the heat map at the future time. Each of the multiple cells can represent a cost for the passive object to occupy the respective cell. In some examples, the heat map may be associated with a reference cost, an obstacle cost, a progress cost, or lane change cost, just to name a few. In some examples, the heat map renderer can generate multiple heat maps over time for use in inference operations by another model (e.g., the map component 104, a planning component 136, etc.). For instance, a series of heat maps can be determined representing possible locations of an object at different times in the future.

In some examples, the model may receive heat map data associated with one or more heat maps. For instance, a heuristic model can output a heat map for a passive and/or an active object. The heat map can represent an area that the object is likely to occupy in the future. Heat maps for different objects can be combined (e.g., aggregated, concatenated, etc.) with a scene context (e.g., based on a top down representation of the environment) for use as input data. For instance, a heat map can be associated with a respective set of costs. Costs associated with the heat map can represent a weight for the respective object to occupy a cell of the heat map. Additional details of determining a heat map are described in U.S. patent application Ser. No. 17/485,041, filed on Sep. 24, 2021, entitled “Optimization Based Planning System,” which is incorporated herein by reference in its entirety.

In some examples, the map component 104 can determine the output data 106 based on receiving a top down representation of the environment (e.g.,, based at least in part on the sensor data and map data, etc.). For example, a vehicle computing device can generate, estimate, or otherwise determine a top down view representing the environment, though other views or representations are also contemplated (e.g., a two-dimensional representation or three-dimensional representation). In various examples, the top down perspective of the environment may comprise one or more multi-channel image(s) such as a first channel, a second channel, and/or a third channel. The vehicle computing device can determine the multi-channel image(s) to represent different attributes of the environment with different channel images. For instance, an image having multiple channels, wherein each channel is representative of some information (semantic or otherwise). In some examples, one of the channel images can represent an object position, a feature of the environment, an object velocity (e.g., of the object 110), an object heading, an object acceleration, an object yaw, an attribute of the object, crosswalk permission (e.g., a crosswalk light or audio state), and traffic light permissibility (e.g., a traffic light state), to name a few. In this way, the top down view can represent objects in the environment (e.g., represented by a bounding box), semantic information about the object (e.g., a classification type), movement information (e.g., velocity information, acceleration information, etc.), and the like. Additional details of using top down representations are described in U.S. patent application Ser. No. 16/504,147, filed on Jul. 5, 2019, entitled “Prediction on Top-Down Scenes Based On Action Data,” and in U.S. patent application Ser. No. 16/151,607, filed on Oct. 4, 2018, entitled “Trajectory Prediction on Top-Down Scenes,” which are incorporated herein by reference in their entirety and for all purposes.

The output data 106 determined by the map component 104 can be used in a variety of ways. For example, map data can be transmitted to a computing device or component configured to control the vehicle 102 in the environment 100 (e.g., determine a trajectory, used as a cost by an algorithm, used as a node in a tree structure, etc.). For example, the map data can be transmitted to the planning component 136 of a vehicle computing device that is configured to determine planning data (e.g., a vehicle trajectory, an object trajectory, an output by a tree structure, etc.) for the vehicle 102 to navigate in the environment. The planning data can include one or more vehicle trajectories (candidate trajectories to avoid objects) and/or one or more object trajectories, just to name a few. The planning data can also or instead represent determinations (e.g., vehicle actions) made by a tree structure that is configured with reference actions corresponding to different map data representing positions of various entities output from the map component 104. The output data 106 can, for example, represent a road policy, traffic policy, semantic information, and/or geometric information usable by the planning component 136 to predict a trajectory to control the vehicle 102 in the environment 100 relative to the objects 108 and 110, the roadway boundary 122, the drivable surface boundary 124, etc. (or polygons associated therewith).

In some examples, the output data 106 by the map component 104 can be used to perform a simulation, control a vehicle (e.g., determine a candidate vehicle trajectory and/or control a propulsion system, a braking system, or a steering system), validate or test performance of a vehicle or component thereof, to name a few. The map component 104 can, for example, determine one or more map features (represented by polygons) for use in a tree structure to control the vehicle 102 (e.g., a reference action associated with an object probability can be included in a tree structure). The polygon(s) output by the map component 104 can improve vehicle planning operations by enabling more realistic reference representations, actions, or the like in a tree structure (e.g., to plan for a greater variance of potential object positions, more accurate roadway boundaries, more accurate drivable surfaces, avoiding and/or navigating construction zones, etc.).

In various examples, a computing device (e.g., a vehicle computing device) may be configured to determine actions for a vehicle to take while operating (e.g., trajectories to use to control the vehicle) based on map data determined by the model. The actions may include a reference action (e.g., one of a group of maneuvers the vehicle is configured to perform in reaction to a dynamic operating environment) such as a right lane change, a left lane change, staying in a lane, going around an obstacle (e.g., double-parked vehicle, a group of pedestrians, etc.), or the like. The actions may additionally include sub-actions, such as speed variations (e.g., maintain velocity, accelerate, decelerate, etc.), positional variations (e.g., changing a position in a lane), or the like. For example, an action may include staying in a lane (action) and adjusting a position of the vehicle in the lane from a centered position to operating on a left side of the lane (sub-action).

For each applicable action and sub-action, the vehicle computing system may implement different model(s) and/or component(s) to simulate future states (e.g., estimated states) by projecting an autonomous vehicle and relevant object(s) forward in the environment for the period of time (e.g., 5 seconds, 8 seconds, 12 seconds, etc.). The model(s) may project the object(s) (e.g., estimate future positions of the object(s)) forward based on a predicted trajectory associated therewith. For instance, the model(s) may predict a trajectory of a vehicle and predict attributes about the vehicle including whether the trajectory will be used by the vehicle to arrive at a predicted location in the future. The vehicle computing device may project the vehicle forward (e.g., estimate future positions of the vehicle) based on the vehicle trajectories output by the model. The estimated state(s) may represent an estimated position (e.g., estimated location) of the autonomous vehicle and an estimated position of the relevant object(s) at a time in the future. In some examples, the vehicle computing device may determine relative data between the autonomous vehicle and the object(s) in the estimated state(s). In such examples, the relative data may include distances, locations, speeds, directions of travel, and/or other factors between the autonomous vehicle and the object. In various examples, the vehicle computing device may determine estimated states at a pre-determined rate (e.g., 10 Hertz, 20 Hertz, 50 Hertz, etc.). In some examples, the rate at which the estimated states are determined may vary over time and/or based on one or more conditions (e.g., speed of the vehicle, speed of objects in the environment, number of objects in the environment, type of operational drive domain (e.g., residential street vs. highway), whether the vehicle is occupied, etc. In at least one example, the estimated states may be performed at a rate of 10 Hertz (e.g., 80 estimated intents over an 8 second period of time).

A training component of a remote computing device, such as the computing device(s) 434 (not shown) and/or the vehicle computing device(s) 404 (not shown) may be implemented to train the map component 104 (in examples when the map component 104 is a machine learned model). Training data may include a wide variety of data, such as previous map data output by the map component 104, static map data, dynamically updated map data, polygon data, probability data, log data, historical data, image data (e.g., a bitmap, heat map, etc.), video data, lidar data, radar data, audio data, other sensor data, previously generated polygons, etc., that is associated with a value (e.g., a desired classification, inference, prediction, etc.). In some examples training data can comprise determinations based on sensor data, such as, bounding boxes (e.g., two-dimensional and/or three-dimensional bounding boxes associated with an object), segmentation information, classification information, an object trajectory, an object probability, object track information, and the like. Such training data may generally be referred to as a “ground truth.” To illustrate, the training data may be used for map generation and, as such, may include a map of an environment that is captured by an autonomous vehicle.

By implementing the map component 104, map information representing entities in the environment can be generated with more accuracy in less time than not using the map component 104. For example, the map information can include a first polygon for the object 110, a second polygon for the drivable surface boundary 124, and a third polygon for the roadway boundary 122 that are determined with improved accuracy to represent how the entities appear in a real-world environment. The planning component 136 can receive the map information and predict trajectories from the vehicle 102 and/or the objects in the environment to improve safety of the vehicle 102 as it navigates in the environment.

FIG. 2 illustrates an example block diagram 200 of an example computer architecture for implementing techniques to determine a map based on images having different points of view, as described herein. For instance, one or more computing devices 202 can include the map component 104 of FIG. 1 to receive input data 204 and perform one or more operations to generate output data 206 representing a map of an environment. In various examples, the computing device(s) 202 can receive the input data 204 for processing and determine output data 206 comprising semantic information, height information, road feature information, and/or one or more polygons to represent entity(ies) in the environment. In some examples, the computing device(s) 202 can be coupled to the vehicle 102 and the techniques can be performed as the vehicle 102 navigates in a real-world environment or a simulated environment. The computing device(s) 202 may represent or otherwise include the functionality of the vehicle computing device(s) 404 and/or the computing device(s) 434.

In some examples, the input data 204 can include sensor data, pose data, vehicle configuration data (e.g., sensor calibration data, settings for a component or machine learned model, etc.), to name a few. For example, the input data 204 can comprise sensor data from one or more sensors associated with the vehicle 102 (e.g., coupled to and/or remote from the vehicle). In some examples, the input data 204 can represent raw sensor data and/or processed sensor data representing an environment of the vehicle 102. The pose data (or other vehicle state data) and vehicle configuration data can be received from a component of the computing device(s) 202, depending on examples.

The map component 104 can determine one or more views of the environment 208 including for example a bird's-eye view representation, a perspective view representation, or other view. The view(s) of the environment 208 can also indicate a geometry of a road surface or other surface in the environment. Each view can be associated with a different range relative to the vehicle 102. In some examples, the map component 104 can determine different views at different ranges to extract features from the environment using advantages of each respective view. The bird's eye view representation of the environment may be used to determine presence of a lane, lane usage, lane directionality, etc. while the perspective view representation of the environment may be used to detect relevant objects, dynamic features, etc. the map component 104 can save computational resources by limiting a range of a bird's-eye view representation.

The view(s) of the environment 208 can be input into a real-time mapping head 210 and/or a road geometry head 212 for further processing. Of course, while the real-time mapping head 210 and road geometry head 212 are shown separate for illustrative purposes, in some examples a single head may be used and/or processing by the real-time mapping head 210 and road geometry head 212 may be performed in parallel by a parallel processor unit.

The real-time mapping head 210 can receive one or more of: the view(s) of the environment 208, track data 214, and map data 216 as input data. The track data 214 may be received from a perception component 218 that is configured to process sensor data to receive an area proximate the vehicle 102. The track data 214 can represent state data associated with one or more objects detected by the vehicle 102 at a previous time. The map data 216 can represent a previous output by the map component 104 and/or static map data and may be stored in a database 220 that is coupled to the vehicle 102 or remote from the vehicle 102. The real-time mapping head 210 can determine real-time map data 222 to include as some or all of the output data 206 based on processing the view(s) of the environment 208, the track data 214, and/or the map data 216. In some examples, the track data 214, and/or the map data 216 can act as an attention system in a machine learned model.

By way of example and not limitation, the map component 104 can represent a decoder that is configured to determine an intermediate output based at least in part on applying an attention algorithm to some of the input data. For example, the decoder can employ a self-attention layer(s) and/or a cross-attention layer(s) to the view(s) of the environment 208, the track data 214, and/or the map data 216 to generate an intermediate output which is usable as input to a first output head (e.g., the real-time mapping head 210) and/or a second output head (e.g., the road geometry head 212). The first and second output heads can generate respective features of the map represented by the output data. By implementing the attention system, the decoder can capture context for an object, lane, or other feature in the environment. The output data 206 can, for example, include semantic descriptions for various features to improve downstream determinations by a planning and/or perception component.

In some examples, the map component 104 can determine a relationship between a first feature and a second feature, and include the relationship (e.g., as a semantic description) in the output data 206. For example, the map component 104 can determine that the object 108 is likely to occupy the crosswalk 130 at a future time based on an orientation of the object 108. As another example, the map component 104 can relate or associate a roadway marking, the pothole 302, or other feature with a particular lane. In some examples, the relationship can represent a connection between two or more lanes that collectively provide a path for the vehicle (e.g., a lane can be associated with an annotation indicating which lanes have a same direction of travel, and so on).

The road geometry head 212 can receive the view(s) of the environment 208 and generate road features 224 and/or height and semantic information 226. The road features 224 can represent features detected in the environment and represented as polylines and/or polygons such as a roadway boundary, a curb, a pothole in the roadway, or other feature. In some examples, the road features 224 may be based at least in part on the lidar data or other sensor data.

The height information (e.g., road height, object height, etc.) can represent context for a road or other feature in the environment. The road height can represent a topology of one or more roadways detected in the environment and the semantic information may represent coordinates for the road height relative to a coordinate system. In some examples, semantic information can indicate a type of roadway, a use roadway, directionality of a roadway, which may be annotated into the output data 206. For example, a bike lane symbol may be added to a lane based on a traffic sign indicating a lane is designated for bicycle use despite a roadway marking not existing in the real-world environment.

The output data 206 can be used in a variety of ways. For example, output data representing the real-time map data 222, the road features 224, and/or the height and semantic information 226 can be used to perform a simulation, control a vehicle, and/or validate or test vehicle performance, just to name a few. For example, the output data 206 can be used for validating, based at least in part on a result of the simulation, an output by a component configured to control the vehicle in the environment at a future time. For instance, the result of the simulation can be used to validate a determination or prediction from a planning component, prediction component, and the like. In some examples, at least a portion of the output data 206 can be stored in a storage device for access at a later time. For example, map data and associated polygon information, etc. may be stored in a database for use as input data and/or training data.

In some examples, a computing device associated with the map component 104 can transmit at least a portion of the output data 206 to a computing device or component configured to control an autonomous vehicle. For example, a list of polygons associated with an environment can be transmitted to a planning component of a vehicle computing device that is configured to determine planning data (e.g., a vehicle trajectory, an object trajectory, an output by a tree search of a tree structure, etc.).

In some examples, the output data 206 can be used to validate or test performance of a vehicle. For example, a safety system, such as a collision avoidance system, can receive polygon information for processing. Additionally or alternatively, performance of a vehicle controller configured to control some aspect of the vehicle (e.g., a braking system, an acceleration system, and the like) can be validated by enabling the vehicle controller to receive the output data 206 as input.

The map associated with the output data 206 can, for example, be configured for use in a decision tree to control the vehicle 102 and/or the vehicle 402. For instance, an entity of the map can be associated with a respective reference action, or node of the tree structure (e.g., as a weight). Including the entity(ies) of the map in a tree structure to associate with reference actions can improve vehicle planning operations by enabling more realistic reference actions in a tree structure (e.g., considering more accurate representations using the map or polygons thereof that can lead to improved actions by the vehicle 102.

In various examples, processing by the map component 104 to generate the output data 206 can be performed in parallel using a GPU, a tensor processing unit (TPU), a parallel processing unit (e.g., configurable to execute executable instructions in parallel, or other processor. That is, the map component 104 can process the view(s) of the environment 208, the track data 214, and/or the map data 216 at substantially a same time to determine near real-time map information.

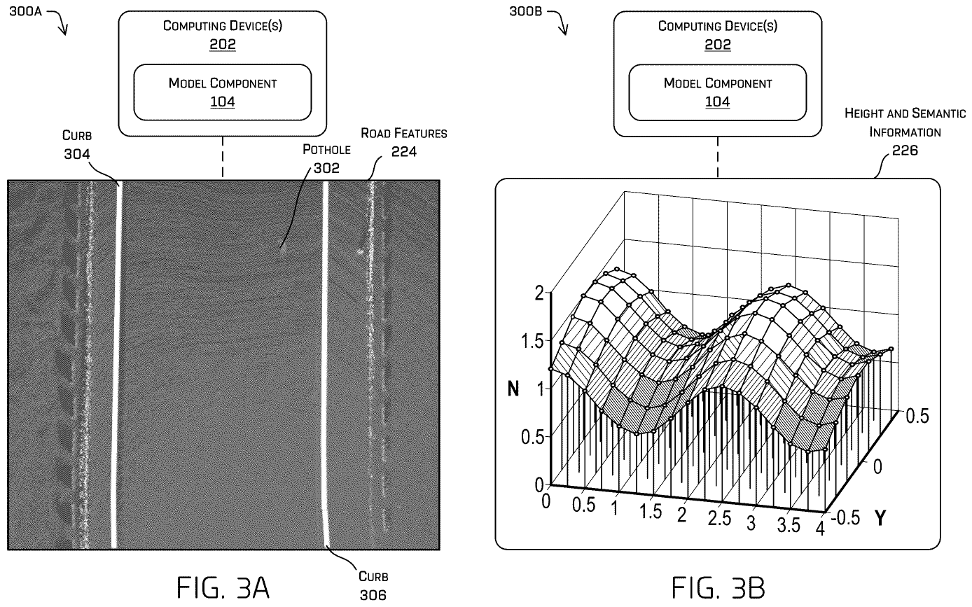

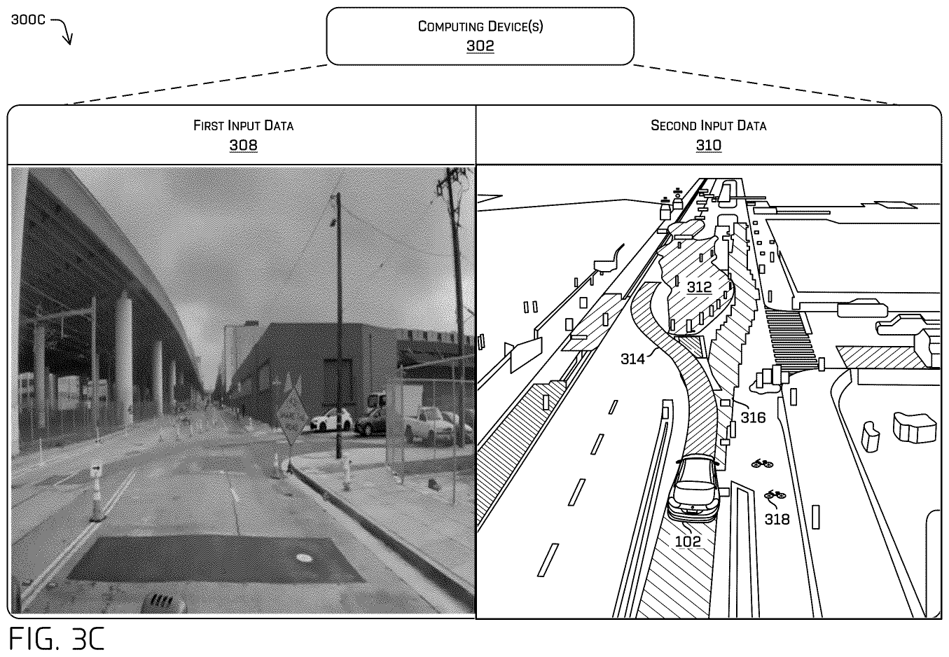

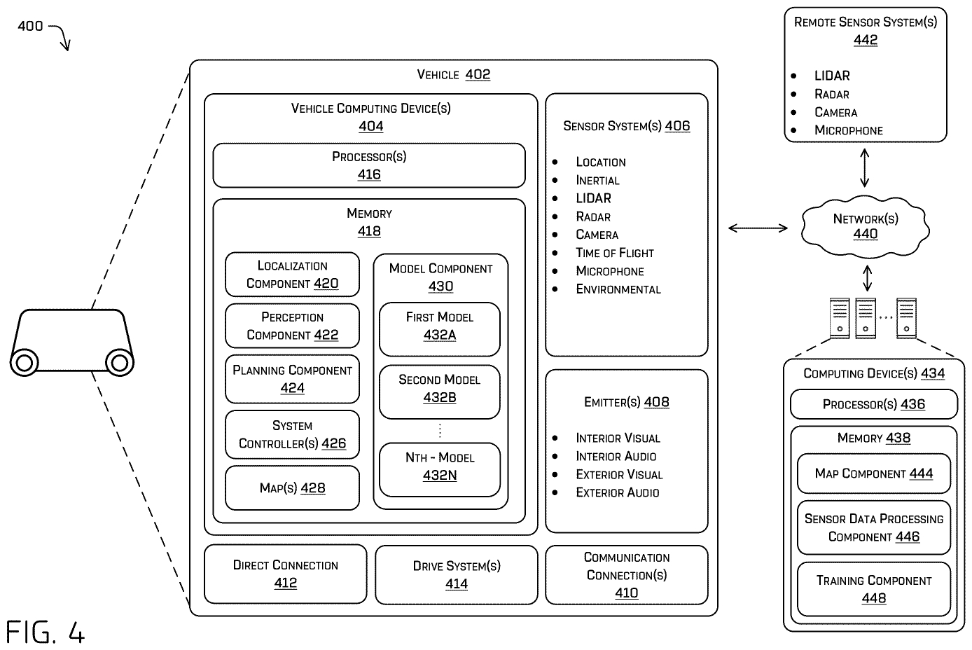

FIG. 3A illustrates an example block diagram 300A of a computing device implementing an example component(s) to determine features in an environment for including in a map. In some examples, the map component 104 can determine the road features 224 based on lidar data (e.g., a dense lidar point cloud). For instance, one or more computing device(s) 202 includes the map component 104 of FIG. 1 to determine some of the road features 224 for including as the output data 106 based on the lidar data. As illustrated in FIG. 3A, the road features can include a pothole 302, a curb 304, a curb 306, just to name a few. The road features 224 may also or instead include a roadway boundary, a drivable surface boundary, an object, a speed bump, and/or a stop line or other roadway marking, among others.

In various examples, the map component 104 can implement a machine learned model (e.g., the road geometry head 212) to determine the road features 224 based on the view(s) of the environment 208. The views of the environment can be based on sensor data associated with the vehicle, and can include a bird's eye view based on processing sensor data from two or more sensors and a perspective view based on processing sensor data from an image sensor (e.g., a camera). The map component 104 can, in some example, receive at least two different views to improve detections of features in the environment. The machine learned model may, in some examples, receive road surface geometry data indicating road surface height, width, type, etc. based on previous map data and/or an output from another component or model. The road surface geometry data can, for example, represent previous road dimensions determined by the vehicle 102, a vehicle in a fleet of vehicles associated with the vehicle 102, and/or a trusted external source (e.g., a map generated by a city, mapping service, etc.).

Though FIG. 3A depicts determining examples features based on lidar data, other sensor data associated with one or more other sensor modalities may also or instead be used. For example, in some examples the map component 104 can determine a road feature for including as the output data 106 based on image data from a camera (e.g., mono or stereo (or more)), lidar data from one or more lidar sensors, or a combination thereof. The map component 104 can also or instead determine the road features 224 based on sensor data received from a sensor representing one or more of: an ultrasonic sensor, a radar sensor, a lidar sensor, an image sensor including a camera (e.g. color sensors, monochromatic sensors, RGB, RGB-D, thermal, depth, intensity, etc.), an infrared sensor, a time of flight (ToF) sensor, a microphone, an inertial sensor, or the like.

FIG. 3B illustrates another example block diagram 300B of a computing device implementing an example component(s) to determine height information and semantic information associated with a map. For example, the computing device(s) 202 can implement the map component 104 to determine height information associated with a roadway, object, or other feature in the environment and semantic information such as coordinates for various points that define a height of a feature.

FIG. 3C illustrates an example block diagram 300C of a computing device implementing an example component(s) to determine output data representing a map based on example input data. For example, the computing device(s) 202 can implement the map component 104 to determine the output data 206 based on first input data 308 and second input data 310. In some examples, the first input data 308 can be determined based at least in part on one or more sensors associated with the vehicle 102. In some examples, the map component 104 can process the first input data 308 and/or the second input data 310 to generate map data indicating that the second lane 316 is available for the vehicle 102 to traverse the environment.

The second input data 310 in FIG. 3C represents a bird's-eye view of the environment of the vehicle 102 which can include regions (e.g., a construction zone 312), lanes (e.g., a first lane 314 and a second lane 316), and/or objects (e.g., another vehicle, traffic indicators such as construction cones, a crosswalk, a pedestrian, etc.). In one example, the lanes 314 and 316 are created due to the construction zone 312. The second input data 310 can also include a traffic indicator 318 to designate the area for bicycles. In some examples, the traffic indicator 318 may not be included in the real-world environment but be added to the second input data 310. The second input data 310 can be determined based at least in part on sensor data from two or more sensors associated with the vehicle 102. In some examples, the second input data 310 can be determined based at least in part on one or more sensors associated with the vehicle 102.

FIG. 4 is a block diagram of an example system 400 for implementing the techniques described herein. In at least one example, the system 400 may include a vehicle, such as vehicle 402.

The vehicle 402 may include one or more vehicle computing devices 404, one or more sensor systems 406, one or more emitters 408, one or more communication connections 410, at least one direct connection 412, and one or more drive system(s) 414.

The vehicle computing device(s) 404 may include one or more processors 416 and memory 418 communicatively coupled with the one or more processors 416. In the illustrated example, the vehicle 402 is an autonomous vehicle; however, the vehicle 402 could be any other type of vehicle, such as a semi-autonomous vehicle, or any other system having at least an image capture device (e.g., a camera enabled smartphone). In some instances, the autonomous vehicle 402 may be an autonomous vehicle configured to operate according to a Level 5 classification issued by the U.S. National Highway Traffic Safety Administration, which describes a vehicle capable of performing all safety-critical functions for the entire trip, with the driver (or occupant) not being expected to control the vehicle at any time. However, in other examples, the autonomous vehicle 402 may be a fully or partially autonomous vehicle having any other level or classification.

In various examples, the vehicle computing device(s) 404 may store sensor data associated with actual location of an object at the end of the set of estimated states (e.g., end of the period of time) and may use this data as training data to train one or more models. In some examples, the vehicle computing device(s) 404 may provide the data to a remote computing device (i.e., computing device separate from vehicle computing device such as one or more computing device(s) 434) for data analysis. In such examples, the remote computing device(s) may analyze the sensor data to determine an actual location, velocity, direction of travel, or the like of the object at the end of the set of estimated states. Additional details of training a machine learned model based on stored sensor data by minimizing differences between actual and predicted positions and/or predicted trajectories is described in U.S. patent application Ser. No. 16/282,201, filed on Mar. 12, 2019, entitled “Motion Prediction Based on Appearance,” which is incorporated herein by reference in its entirety and for all purposes.

In the illustrated example, the memory 418 of the vehicle computing device(s) 404 stores a localization component 420, a perception component 422, a planning component 424, one or more system controllers 426, one or more maps 428, and a model component 430 including one or more model(s), such as a first model 432A, a second model 432B, up to an Nth model 432N (collectively “the model(s) 432”), where N is an integer. Though depicted in FIG. 4 as residing in the memory 418 for illustrative purposes, it is contemplated that the localization component 420, a perception component 422, a planning component 424, one or more system controllers 426, one or more maps 428, and/or the model component 430 including the model(s) 432 may additionally, or alternatively, be accessible to the vehicle 402 (e.g., stored on, or otherwise accessible by, memory remote from the vehicle 402, such as, for example, on memory 438 of the computing device(s) 434). In some examples, the model(s) 432 can provide functionality associated with the map component 104. In some examples, the model(s) 432 can include one or more of: a machine learned model, a statistical model, a heuristic model, or a combination thereof.

In at least one example, the localization component 420 may include functionality to receive data from the sensor system(s) 406 to determine a position and/or orientation of the vehicle 402 (e.g., one or more of an x-, y-, z-position, roll, pitch, or yaw). For example, the localization component 420 may include and/or request/receive a map of an environment, such as from map(s) 428 and/or map component 444, and may continuously determine a location and/or orientation of the autonomous vehicle within the map. In some instances, the localization component 420 may utilize SLAM (simultaneous localization and mapping), CLAMS (calibration, localization and mapping, simultaneously), relative SLAM, bundle adjustment, non-linear least squares optimization, or the like to receive image data, lidar data, radar data, IMU data, GPS data, wheel encoder data, and the like to accurately determine a location of the autonomous vehicle. In some instances, the localization component 420 may provide data to various components of the vehicle 402 to determine an initial position of an autonomous vehicle for determining the relevance of an object to the vehicle 402, as discussed herein.

In some instances, the perception component 422 may include functionality to perform object detection, segmentation, and/or classification. In some examples, the perception component 422 may provide processed sensor data that indicates a presence of an object (e.g., entity) that is proximate to the vehicle 402 and/or a classification of the object as an object type (e.g., car, pedestrian, cyclist, animal, building, tree, road surface, curb, sidewalk, unknown, etc.). In some examples, the perception component 422 may provide processed sensor data that indicates a presence of a stationary entity that is proximate to the vehicle 402 and/or a classification of the stationary entity as a type (e.g., building, tree, road surface, curb, sidewalk, unknown, etc.). In additional or alternative examples, the perception component 422 may provide processed sensor data that indicates one or more features associated with a detected object (e.g., a tracked object) and/or the environment in which the object is positioned. In some examples, features associated with an object may include, but are not limited to, an x-position (global and/or local position), a y-position (global and/or local position), a z-position (global and/or local position), an orientation (e.g., a roll, pitch, yaw), an object type (e.g., a classification), a velocity of the object, an acceleration of the object, an extent of the object (size), etc. Features associated with the environment may include, but are not limited to, a presence of another object in the environment, a state of another object in the environment, a time of day, a day of a week, a season, a weather condition, an indication of darkness/light, etc.

In general, the planning component 424 may determine a path for the vehicle 402 to follow to traverse through an environment. For example, the planning component 424 may determine various routes and trajectories and various levels of detail. For example, the planning component 424 may determine a route to travel from a first location (e.g., a current location) to a second location (e.g., a target location). For the purpose of this discussion, a route may include a sequence of waypoints for travelling between two locations. As non-limiting examples, waypoints include streets, intersections, global positioning system (GPS) coordinates, etc. Further, the planning component 424 may generate an instruction for guiding the autonomous vehicle along at least a portion of the route from the first location to the second location. In at least one example, the planning component 424 may determine how to guide the autonomous vehicle from a first waypoint in the sequence of waypoints to a second waypoint in the sequence of waypoints. In some examples, the instruction may be a trajectory, or a portion of a trajectory. In some examples, multiple trajectories may be substantially simultaneously generated (e.g., within technical tolerances) in accordance with a receding horizon technique, wherein one of the multiple trajectories is selected for the vehicle 402 to navigate.

In some examples, the planning component 424 may include a prediction component to generate predicted trajectories of objects (e.g., objects) in an environment and/or to generate predicted candidate trajectories for the vehicle 402. For example, a prediction component may generate one or more predicted trajectories for objects within a threshold distance from the vehicle 402. In some examples, a prediction component may measure a trace of an object and generate a trajectory for the object based on observed and predicted behavior.

In at least one example, the vehicle computing device(s) 404 may include one or more system controllers 426, which may be configured to control steering, propulsion, braking, safety, emitters, communication, and other systems of the vehicle 402. The system controller(s) 426 may communicate with and/or control corresponding systems of the drive system(s) 414 and/or other components of the vehicle 402.

The memory 418 may further include one or more maps 428 that may be used by the vehicle 402 to navigate within the environment. For the purpose of this discussion, a map may be any number of data structures modeled in two dimensions, three dimensions, or N-dimensions that are capable of providing information about an environment, such as, but not limited to, topologies (such as intersections), streets, mountain ranges, roads, terrain, and the environment in general. In some instances, a map may include, but is not limited to: texture information (e.g., color information (e.g., RGB color information, Lab color information, HSV/HSL color information), and the like), intensity information (e.g., lidar information, radar information, and the like); spatial information (e.g., image data projected onto a mesh, individual “surfels” (e.g., polygons associated with individual color and/or intensity)), reflectivity information (e.g., specularity information, retroreflectivity information, BRDF information, BSSRDF information, and the like). In one example, a map may include a three-dimensional mesh of the environment. In some examples, the vehicle 402 may be controlled based at least in part on the map(s) 428. That is, the map(s) 428 may be used in connection with the localization component 420, the perception component 422, and/or the planning component 424 to determine a location of the vehicle 402, detect objects in an environment, generate routes, determine actions and/or trajectories to navigate within an environment.

In some examples, the one or more maps 428 may be stored on a remote computing device(s) (such as the computing device(s) 434) accessible via one or more networks 440. In some examples, multiple maps 428 may be stored based on, for example, a characteristic (e.g., type of entity, time of day, day of week, season of the year, etc.). Storing multiple maps 428 may have similar memory requirements, but increase the speed at which data in a map may be accessed.

As illustrated in FIG. 4, the vehicle computing device(s) 404 may include a model component 430. The model component 430 may be configured to perform the functionality of the map component 104, including determining features from different points of view in near real-time. In various examples, the model component 430 may receive one or more features associated with the detected object(s) from the perception component 422 and/or from the sensor system(s) 406. In some examples, the model component 430 may receive environment characteristics (e.g., environmental factors, etc.) and/or weather characteristics (e.g., weather factors such as snow, rain, ice, etc.) from the perception component 422 and/or the sensor system(s) 406. While shown separately in FIG. 4, the model component 430 could be part of the perception component 422, the planning component 424 or other component(s) of the vehicle 402.

In various examples, the model component 430 may send predictions from the one or more models 432 that may be used by the planning component 424 to generate one or more predicted trajectories of the object (e.g., direction of travel, speed, etc.) and/or one or more predicted trajectories of the object (e.g., direction of travel, speed, etc.), such as from the prediction component thereof. In some examples, the planning component 424 may determine one or more actions (e.g., reference actions and/or sub-actions) for the vehicle 402, such as vehicle candidate trajectories. In some examples, the model component 430 may be configured to determine whether an object occupies a future position based at least in part on the one or more actions for the vehicle 402. In some examples, the model component 430 may be configured to determine the actions that are applicable to the environment, such as based on environment characteristics, weather characteristics, another object, or the like.

The model component 430 may generate a map comprising polygons to represent an object, region such as a drivable surface, construction zone, etc. The data output by the model component 430 usable for various prediction operations and/or planning operations such as determining sets of estimated states of the vehicle and one or more detected objects forward in the environment over a time period. The model component 430 may generate output data usable to determine a set of estimated states for each action (e.g., reference action and/or sub-action) determined to be applicable to the environment. The sets of estimated states may include one or more estimated states, each estimated state including an estimated position of the vehicle and an estimated position of a detected object(s). In some examples, the estimated states may include estimated positions of the detected objects at an initial time (T=0) (e.g., current time).

The estimated positions may be determined based on a detected trajectory and/or predicted trajectories associated with the object. In some examples, the estimated positions may be determined based on an assumption of substantially constant velocity and/or substantially constant trajectory (e.g., little to no lateral movement of the object). In some examples, the estimated positions (and/or potential trajectories) may be based on passive and/or active prediction. In some examples, the model component 430 can output data to determine planning data that may utilize physics and/or geometry-based techniques, machine learning, linear temporal logic, tree search methods, heat maps, and/or other techniques for determining predicted trajectories and/or estimated positions of objects.

In various examples, the estimated states may be generated periodically throughout the time period. For example, the model component 430 can output map data usable to generate estimated states at 0.1 second intervals throughout the time period. The estimated states may be used by the planning component 424 in determining an action for the vehicle 402 to take in an environment.

In various examples, the model component 430 may utilize machine learned techniques to perform one or more map operations associated with the map component 104 of FIG. 1, and so on. In such examples, the machine learned algorithms may be trained to determine, based on sensor data and/or previous predictions by the model, representations of an environment including how an object(s) may behave in a particular way relative to the vehicle 402 at a particular time during a set of estimated states (e.g., time period). In such examples, one or more of the vehicle 402 state (position, velocity, acceleration, trajectory, etc.) and/or the object state, classification, etc. may be input into such a machine learned model and, in turn, a trajectory prediction may be output by the model.

In various examples, characteristics associated with each object type may be used by the planning component 424 to determine a position, a trajectory, a velocity, or an acceleration associated with the object. Examples of characteristics of an object type may include, but not be limited to: a maximum longitudinal acceleration, a maximum lateral acceleration, a maximum vertical acceleration, a maximum speed, maximum change in direction for a given speed, and the like.

As can be understood, the components discussed herein (e.g., the localization component 420, the perception component 422, the planning component 424, the system controller(s) 426, the one or more maps 428, the model component 430 including the model(s) 432 are described as divided for illustrative purposes. However, the operations performed by the various components may be combined or performed in any other component.

While examples are given in which the techniques described herein are implemented by a planning component and/or a model component of the vehicle, in some examples, some or all of the techniques described herein could be implemented by another system of the vehicle, such as a secondary safety system. Generally, such an architecture can include a first computing device to control the vehicle 402 and a secondary safety system that operates on the vehicle 402 to validate operation of the primary system and to control the vehicle 402 to avoid collisions.

In some instances, aspects of some or all of the components discussed herein may include any models, techniques, and/or machine learned techniques. For example, in some instances, the components in the memory 418 (and the memory 438, discussed below) may be implemented as a neural network.

As described herein, an exemplary neural network is a technique which passes input data through a series of connected layers to produce an output. Each layer in a neural network may also comprise another neural network, or may comprise any number of layers (whether convolutional or not). As can be understood in the context of this disclosure, a neural network may utilize machine learning, which may refer to a broad class of such techniques in which an output is generated based on learned parameters.

Although discussed in the context of neural networks, any type of machine learning may be used consistent with this disclosure. For example, machine learning techniques may include, but are not limited to, regression techniques (e.g., ordinary least squares regression (OLSR), linear regression, logistic regression, stepwise regression, multivariate adaptive regression splines (MARS), locally estimated scatterplot smoothing (LOESS)), instance-based techniques (e.g., ridge regression, least absolute shrinkage and selection operator (LASSO), elastic net, least-angle regression (LARS)), decisions tree techniques (e.g., classification and regression tree (CART), iterative dichotomiser 3 (ID3), Chi-squared automatic interaction detection (CHAID), decision stump, conditional decision trees), Bayesian techniques (e.g., naïve Bayes, Gaussian naïve Bayes, multinomial naïve Bayes, average one-dependence estimators (AODE), Bayesian belief network (BNN), Bayesian networks), clustering techniques (e.g., k-means, k-medians, expectation maximization (EM), hierarchical clustering), association rule learning techniques (e.g., perceptron, back-propagation, hopfield network, Radial Basis Function Network (RBFN)), deep learning techniques (e.g., Deep Boltzmann Machine (DBM), Deep Belief Networks (DBN), Convolutional Neural Network (CNN), Stacked Auto-Encoders), Dimensionality Reduction Techniques (e.g., Principal Component Analysis (PCA), Principal Component Regression (PCR), Partial Least Squares Regression (PLSR), Sammon Mapping, Multidimensional Scaling (MDS), Projection Pursuit, Linear Discriminant Analysis (LDA), Mixture Discriminant Analysis (MDA), Quadratic Discriminant Analysis (QDA), Flexible Discriminant Analysis (FDA)), Ensemble Techniques (e.g., Boosting, Bootstrapped Aggregation (Bagging), AdaBoost, Stacked Generalization (blending), Gradient Boosting Machines (GBM), Gradient Boosted Regression Trees (GBRT), Random Forest), SVM (support vector machine), supervised learning, unsupervised learning, semi-supervised learning, etc. Additional examples of architectures include neural networks such as ResNet50, ResNet101, VGG, DenseNet, PointNet, and the like.

In at least one example, the sensor system(s) 406 may include lidar sensors, radar sensors, ultrasonic transducers, sonar sensors, location sensors (e.g., GPS, compass, etc.), inertial sensors (e.g., inertial measurement units (IMUs), accelerometers, magnetometers, gyroscopes, etc.), image sensors including cameras (e.g., RGB, RGB-D, thermal, IR, intensity, depth, time of flight, etc.), microphones, wheel encoders, environment sensors (e.g., temperature sensors, humidity sensors, light sensors, pressure sensors, etc.), etc. The sensor system(s) 406 may include multiple instances of each of these or other types of sensors. For instance, the lidar sensors may include individual lidar sensors located at the corners, front, back, sides, and/or top of the vehicle 402. As another example, the camera sensors may include multiple cameras disposed at various locations about the exterior and/or interior of the vehicle 402. The sensor system(s) 406 may provide input to the vehicle computing device(s) 404. Additionally, or in the alternative, the sensor system(s) 406 may send sensor data, via the one or more networks 440, to the computing device(s) 434 at a particular frequency, after a lapse of a predetermined period of time, in near real-time, etc.

The vehicle 402 may also include the one or more emitters 408 for emitting light and/or sound. The emitter(s) 408 may include interior audio and visual emitters to communicate with passengers of the vehicle 402. By way of example and not limitation, interior emitters may include speakers, lights, signs, display screens, touch screens, haptic emitters (e.g., vibration and/or force feedback), mechanical actuators (e.g., seatbelt tensioners, seat positioners, headrest positioners, etc.), and the like. The emitter(s) 408 may also include exterior emitters. By way of example and not limitation, the exterior emitters may include lights to signal a direction of travel or other indicator of vehicle action (e.g., indicator lights, signs, light arrays, etc.), and one or more audio emitters (e.g., speakers, speaker arrays, horns, etc.) to audibly communicate with pedestrians or other nearby vehicles, one or more of which comprising acoustic beam steering technology.

The vehicle 402 may also include one or more communication connections 410 that enable communication between the vehicle 402 and one or more other local or remote computing device(s). For instance, the communication connection(s) 410 may facilitate communication with other local computing device(s) on the vehicle 402 and/or the drive system(s) 414. Also, the communication connection(s) 410 may allow the vehicle to communicate with other nearby computing device(s) (e.g., the computing device(s) 434, other nearby vehicles, etc.) and/or one or more remote sensor system(s) 442 for receiving sensor data. The communications connection(s) 410 also enable the vehicle 402 to communicate with a remote teleoperations computing device or other remote services.

The communications connection(s) 410 may include physical and/or logical interfaces for connecting the vehicle computing device(s) 404 to another computing device or a network, such as the network(s) 440. For example, the communications connection(s) 410 can enable Wi-Fi-based communication such as via frequencies defined by the IEEE 802.11 standards, short range wireless frequencies such as Bluetooth, cellular communication (e.g., 2G, 3G, 4G, 4G LTE, 5G, etc.) or any suitable wired or wireless communications protocol that enables the respective computing device to interface with the other computing device(s).

As mentioned, the vehicle 402 may include one or more drive systems 414. In some examples, the vehicle 402 may have a single drive system 414. In at least one example, if the vehicle 402 has multiple drive systems 414, individual drive systems 414 may be positioned on opposite ends of the vehicle 402 (e.g., the front and the rear, etc.). In at least one example, the drive system(s) 414 may include one or more sensor systems to detect conditions of the drive system(s) 414 and/or the surroundings of the vehicle 402. By way of example and not limitation, the sensor system(s) may include one or more wheel encoders (e.g., rotary encoders) to sense rotation of the wheels of the drive systems, inertial sensors (e.g., inertial measurement units, accelerometers, gyroscopes, magnetometers, etc.) to measure orientation and acceleration of the drive systems, cameras or other image sensors, ultrasonic sensors to acoustically detect objects in the surroundings of the drive system, lidar sensors, radar sensors, etc. Some sensors, such as the wheel encoders may be unique to the drive system(s) 414. In some cases, the sensor system(s) on the drive system(s) 414 may overlap or supplement corresponding systems of the vehicle 402 (e.g., sensor system(s) 406).

The drive system(s) 414 may include many of the vehicle systems, including a high voltage battery, a motor to propel the vehicle, an inverter to convert direct current from the battery into alternating current for use by other vehicle systems, a steering system including a steering motor and steering rack (which can be electric), a braking system including hydraulic or electric actuators, a suspension system including hydraulic and/or pneumatic components, a stability control system for distributing brake forces to mitigate loss of traction and maintain control, an HVAC system, lighting (e.g., lighting such as head/tail lights to illuminate an exterior surrounding of the vehicle), and one or more other systems (e.g., cooling system, safety systems, onboard charging system, other electrical components such as a DC/DC converter, a high voltage junction, a high voltage cable, charging system, charge port, etc.). Additionally, the drive system(s) 414 may include a drive system controller which may receive and preprocess data from the sensor system(s) and to control operation of the various vehicle systems. In some examples, the drive system controller may include one or more processors and memory communicatively coupled with the one or more processors. The memory may store one or more modules to perform various functionalities of the drive system(s) 414. Furthermore, the drive system(s) 414 may also include one or more communication connection(s) that enable communication by the respective drive system with one or more other local or remote computing device(s).

In at least one example, the direct connection 412 may provide a physical interface to couple the one or more drive system(s) 414 with the body of the vehicle 402. For example, the direct connection 412 may allow the transfer of energy, fluids, air, data, etc. between the drive system(s) 414 and the vehicle. In some instances, the direct connection 412 may further releasably secure the drive system(s) 414 to the body of the vehicle 402.

In at least one example, the localization component 420, the perception component 422, the planning component 424, the system controller(s) 426, the one or more maps 428, and the model component 430, may process sensor data, as described above, and may send their respective outputs, over the network(s) 440, to the computing device(s) 434. In at least one example, the localization component 420, the perception component 422, the planning component 424, the system controller(s) 426, the one or more maps 428, and the model component 430 may send their respective outputs to the computing device(s) 434 at a particular frequency, after a lapse of a predetermined period of time, in near real-time, etc.

In some examples, the vehicle 402 may send sensor data to the computing device(s) 434 via the network(s) 440. In some examples, the vehicle 402 may receive sensor data from the computing device(s) 434 and/or remote sensor system(s) 442 via the network(s) 440. The sensor data may include raw sensor data and/or processed sensor data and/or representations of sensor data. In some examples, the sensor data (raw or processed) may be sent and/or received as one or more log files.

The computing device(s) 434 may include processor(s) 436 and a memory 438 storing the map component 444, a sensor data processing component 446, and a training component 448. In some examples, the map component 444 may include functionality to generate maps of various resolutions. In such examples, the map component 444 may send one or more maps to the vehicle computing device(s) 404 for navigational purposes. In various examples, the sensor data processing component 446 may be configured to receive data from one or more remote sensors, such as sensor system(s) 406 and/or remote sensor system(s) 442. In some examples, the sensor data processing component 446 may be configured to process the data and send processed sensor data to the vehicle computing device(s) 404, such as for use by the model component 430 (e.g., the model(s) 432). In some examples, the sensor data processing component 446 may be configured to send raw sensor data to the vehicle computing device 404.

In some instances, the training component 448 can include functionality to train a machine learning model to output probabilities for whether an occluded region is free of any objects or whether the occluded region is occupied by a static obstacle or a dynamic object. For example, the training component 448 can receive sensor data that represents an object traversing through an environment for a period of time, such as 0.1 milliseconds, 1 second, 3, seconds, 5 seconds, 7 seconds, and the like. At least a portion of the sensor data can be used as an input to train the machine learning model.

In some instances, the training component 448 may be executed by the processor(s) 436 to train a machine learning model based on training data. The training data may include a wide variety of data, such as sensor data, audio data, image data, map data, inertia data, vehicle state data, historical data (log data), or a combination thereof, that is associated with a value (e.g., a desired classification, inference, prediction, etc.). Such values may generally be referred to as a “ground truth.” To illustrate, the training data may be used for determining risk associated with occluded regions and, as such, may include data representing an environment that is captured by an autonomous vehicle and that is associated with one or more classifications or determinations. In some examples, such a classification may be based on user input (e.g., user input indicating that the data depicts a specific risk) or may be based on the output of another machine learned model. In some examples, such labeled classifications (or more generally, the labeled output associated with training data) may be referred to as ground truth.

In some instances, the training component 448 can include functionality to train a machine learning model to output classification values. For example, the training component 448 can receive data that represents labelled collision data (e.g. publicly available data, sensor data, and/or a combination thereof). At least a portion of the data can be used as an input to train the machine learning model. Thus, by providing data where the vehicle traverses an environment, the training component 448 can be trained to output occluded value(s) associated with objects and/or occluded region(s), as discussed herein.

In some examples, the training component 448 can include training data that has been generated by a simulator. For example, simulated training data can represent examples where a vehicle collides with an object in an environment or nearly collides with an object in an environment, to provide additional training examples.

The processor(s) 416 of the vehicle 402 and the processor(s) 436 of the computing device(s) 434 may be any suitable processor capable of executing instructions to process data and perform operations as described herein. By way of example and not limitation, the processor(s) 416 and 436 may comprise one or more Central Processing Units (CPUs), Graphics Processing Units (GPUs), or any other device or portion of a device that processes electronic data to transform that electronic data into other electronic data that may be stored in registers and/or memory. In some examples, integrated circuits (e.g., ASICs, etc.), gate arrays (e.g., FPGAs, etc.), and other hardware devices may also be considered processors in so far as they are configured to implement encoded instructions.

Memory 418 and memory 438 are examples of non-transitory computer-readable media. The memory 418 and memory 438 may store an operating system and one or more software applications, instructions, programs, and/or data to implement the methods described herein and the functions attributed to the various systems. In various implementations, the memory may be implemented using any suitable memory technology, such as static random access memory (SRAM), synchronous dynamic RAM (SDRAM), nonvolatile/Flash-type memory, or any other type of memory capable of storing information. The architectures, systems, and individual elements described herein may include many other logical, programmatic, and physical components, of which those shown in the accompanying figures are merely examples that are related to the discussion herein.

It should be noted that while FIG. 4 is illustrated as a distributed system, in alternative examples, components of the vehicle 402 may be associated with the computing device(s) 434 and/or components of the computing device(s) 434 may be associated with the vehicle 402. That is, the vehicle 402 may perform one or more of the functions associated with the computing device(s) 434, and vice versa.

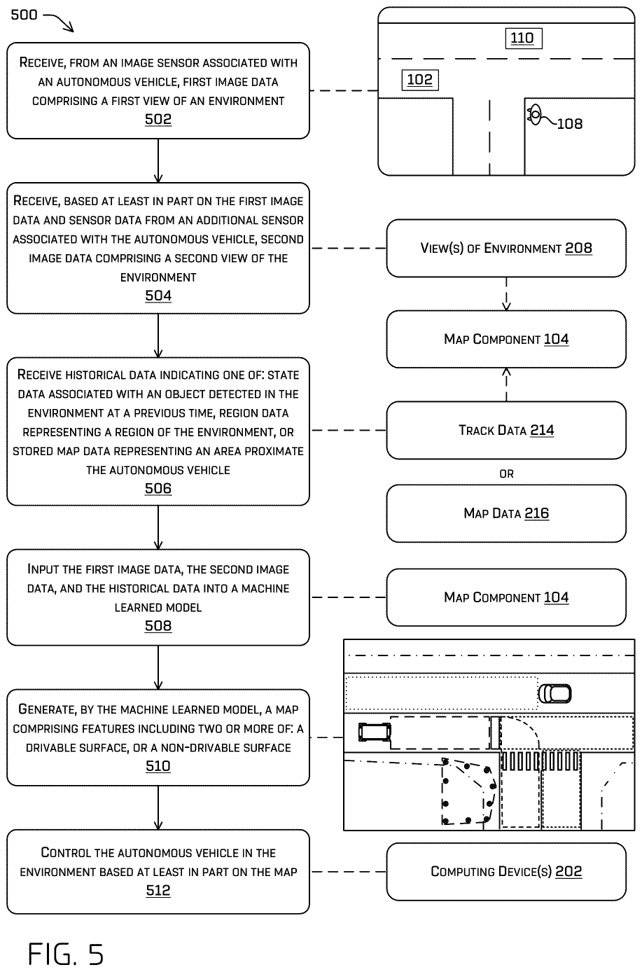

FIG. 5 is a flowchart depicting an example process 500 for determining a map using an example component(s) and using the map to control an autonomous vehicle in an environment. Some or all of the process 500 may be performed by one or more components in FIGS. 1-4, as described herein. For example, some or all of the process 500 can be performed by the computing device(s) 202, the vehicle computing device(s) 404, or the computing device(s) 434.

At operation 502, the process may include receiving, from a sensor associated with an autonomous vehicle, first sensor data comprising a first view of an environment. In some examples, the operation 502 may include a computing device (e.g., the computing device(s) 202 or the vehicle computing device(s) 404) implementing the map component 104 (or the model component 430) to receive an image (e.g., a bitmap, top-down representation of an environment, a heat map(s), etc.) having a first view of the environment. In various examples, the image can be based at least in part on prediction data, state data, log data, map data, sensor data, and/or environment data associated with one or more autonomous vehicles. The image can represent a simulated environment or a real-world environment that includes one or more objects (e.g., static and/or dynamic), traffic signals, drivable surfaces, or roadway boundaries, to represent.

In some examples, the operation 502 can include receiving input data that includes a top-down representation of the environment, a perspective representation, or features of the environment such as the vehicle 102, the vehicle 402, and/or one or more objects. By way of example and not limitation, the image data can be associated with a camera coupled to the vehicle 102 have a perspective relative to the vehicle 102.

At operation 504, the process may include determining, based at least in part on the first sensor data and second sensor data from an additional sensor associated with the autonomous vehicle, image data comprising a second view of the environment. In some examples, the operation 504 may include the map component 104 determining a second view (e.g., a bird's eye view) different form the first view based on the sensor data from a first sensor (e.g., the camera) and additional sensor data from a second sensor (e.g., a lidar sensor). In various examples, the second image can be based at least in part on prediction data, state data, log data, map data, and/or environment data associated with one or more autonomous vehicles.

At operation 506, the process may include receiving historical data indicating one of: state data associated with an object detected in the environment at a previous time, region data representing a region of the environment, or stored map data representing an area proximate the autonomous vehicle. In some examples, the operation 506 may include the map component 104 receiving state data associated with an autonomous vehicle and/or an object(s), region data associated with an occluded region, construction zone, etc., static map data (e.g., non-interactive map information), and/or stored map data. In some examples, the historical data can include data previously output by a component of the vehicle computing device(s) 404 such as the perception component 422, the planning component 424, map(s) 428, model component 430 (having the functionality of the map component 104), etc.).

In some examples, the computing device may receive data associated with the operations 502, 504, and 506 at approximately a same time.

At operation 508, the process may include inputting the first sensor data, the image data, and the historical data into a machine learned model. In some examples, the operation 508 may include the map component 104 receiving input data representing multiple views of an environment, a previously tracked object(s), state data, and so on.

At operation 510, the process may include generating, by the machine learned model, a map comprising features including a drivable surface or a non-drivable surface. In some examples, the operation 510 may include the map component 104 generating the output data 106 or the output data 206 based on the first input data 308 and the second input data 310. The map can include, for example, lanes, lanes connections, lane directionality, traffic indicators such as a stop line crosswalk, roadway marling (e.g., the traffic indicator 318), among others. The map can include a roadway boundary (e.g., the roadway boundary 122), a drivable surface boundary (e.g., the drivable surface boundary 124), a non-drivable surface (e.g., a surface outside a boundary of a drivable surface), etc.

At operation 512, the process may include controlling the autonomous vehicle in the environment based at least in part on the map. In some examples, the operation 512 may include the computing device(s) 202 sending the output data 106 or the output data 206 to a planning component (e.g., the planning component 136 or the planning component 424) for determining planning data usable to control the vehicle (e.g., the vehicle 102) in a real-world environment. For example, the planning component 136 can determine a trajectory to cause the vehicle 102 to traverse or navigate in the environment 100. In some examples, the planning component 424 of the vehicle computing device can control operation of the vehicle 402 based at least in part on features of the map output by the model component 430. In some examples, a planning component (e.g., the planning component 424) can output one or more candidate trajectories for the vehicle to use to avoid a collision with an object (e.g., to determine an action for an autonomous vehicle to navigate in relation to the object). Additional details of controlling a vehicle using one or more outputs from one or more modes are discussed throughout the disclosure.

In various examples, process 500 may return to operation 502 after performing operations 510 or 512. In such examples, the vehicle may continuously monitor the environment for potential collisions and update/modify decisions regarding whether to engage a safety system or not based on an updated list of polygons (which may, in at least some examples, include performing one or more maneuvers to mitigate or minimize an impact). In any of the examples described herein, the process may repeat with a given frequency and generate a list of polygons associated with one or more multiple times in the future for making the determinations above.

FIG. 5 illustrates an example process in accordance with examples of the disclosure. The process is illustrated as logical flow graphs, each operation of which represents a sequence of operations that can be implemented in hardware, software, or a combination thereof. In the context of software, the operations represent computer-executable instructions stored on one or more computer-readable storage media that, when executed by one or more processors, perform the recited operations. Generally, computer-executable instructions include routines, programs, objects, components, data structures, and the like that perform particular functions or implement particular abstract data types. The order in which the operations are described is not intended to be construed as a limitation, and any number of the described operations can be omitted or combined in any order and/or in parallel to implement the processes. In some embodiments, one or more operations of the method may be omitted entirely. By way of example and not limitation, operations 506, 508, 510, and 512 may be performed without performing operations 502, 504, and/or 506. Moreover, the methods described herein can be combined in whole or in part with each other or with other methods.

The methods described herein represent sequences of operations that can be implemented in hardware, software, or a combination thereof. In the context of software, the blocks represent computer-executable instructions stored on one or more computer-readable storage media that, when executed by one or more processors, perform the recited operations. Generally, computer-executable instructions include routines, programs, objects, components, data structures, and the like that perform particular functions or implement particular abstract data types. The order in which the operations are described is not intended to be construed as a limitation, and any number of the described operations can be omitted or combined in any order and/or in parallel to implement the processes.

The various techniques described herein may be implemented in the context of computer-executable instructions or software, such as program modules, that are stored in computer-readable storage and executed by the processor(s) of one or more computing devices such as those illustrated in the figures. Generally, program modules include routines, programs, objects, components, data structures, etc., and define operating logic for performing particular tasks or implement particular abstract data types.

Other architectures may be used to implement the described functionality and are intended to be within the scope of this disclosure. Furthermore, although specific distributions of responsibilities are defined above for purposes of discussion, the various functions and responsibilities might be distributed and divided in different ways, depending on circumstances.

Similarly, software may be stored and distributed in various ways and using different means, and the particular software storage and execution configurations described above may be varied in many different ways. Thus, software implementing the techniques described above may be distributed on various types of computer-readable media, not limited to the forms of memory that are specifically described.

### EXAMPLE CLAUSES

Any of the example clauses in this section may be used with any other of the example clauses and/or any of the other examples or embodiments described herein.

A: A system comprising: one or more processors; and one or more non-transitory computer-readable media storing computer-executable instructions that, when executed, cause the one or more processors to perform operations comprising: receiving, from a sensor associated with an autonomous vehicle, first sensor data comprising a first view of an environment; determining, based at least in part on the first sensor data and second sensor data from an additional sensor associated with the autonomous vehicle, image data comprising a second view of the environment, the second view different from the first view; receiving historical data indicating one of: state data associated with an object detected in the environment at a previous time, region data representing a region of the environment, or stored map data representing an area proximate the autonomous vehicle; inputting the first sensor data, the image data, and the historical data into a machine learned model; generating, by the machine learned model, a map comprising features including a drivable surface or a non-drivable surface; and controlling the autonomous vehicle in the environment based at least in part on the map.

B: The system of paragraph A, wherein: the first view of the environment is a perspective view relative to the autonomous vehicle, the second view of the environment is an elevation view relative to an area above the autonomous vehicle, and the operations further comprising: determining a first feature of the environment based at least in part on the perspective view and a second feature of the environment based at least in part on the elevation view; and including the first feature and the second feature in the map.

C: The system of paragraph A or B, wherein the machine learned model represents a decoder, and the operations further comprising: determining, by the decoder, an intermediate output based at least in part on a self-attention layer or a cross-attention layer; determining, by a first output head of the decoder and based at least in part on the intermediate output, a first feature of the map; and determining, by a second output head of the decoder and based at least in part on the intermediate output, a second feature of the map.

D: The system of any of paragraphs A-C, wherein the machine learned model comprises a first model to determine a first feature of the features and a second model to determine a second feature of the features, and the operations further comprising: one of: determining the first feature by the first model and the second feature by the second model in parallel by a parallel processing unit, or determining the first feature by the first model at a first time and the second feature by the second model at a second time after the first time.

E: The system of any of paragraphs A-D, wherein the map further comprises at least one of: a lane, a connection between two or more lanes, a boundary of the drivable surface, identification of a construction zone, a curb, a crosswalk, a traffic indicator, a static object, a dynamic object, or road rules for the autonomous vehicle and the object.

F: One or more non-transitory computer-readable media storing instructions executable by one or more processors, wherein the instructions, when executed, cause the one or more processors to perform operations comprising: determining, based at least in part on first sensor data associated with a first sensor of a vehicle, first data comprising a first view of an environment; determining, based at least in part on the first sensor data and second sensor data associated with a second sensor of the vehicle, second data comprising a second view of the environment, the second view different from the first view; receiving third data representing state data associated with a dynamic object detected in the environment at a previous time; inputting the first data, the second data, and the third data into a machine learned model; and receiving, from the machine learned model, output data representing features for including in a map, one of the features comprising a drivable surface that is defined at least in part on the first view of the first data and the second view of the second data.

G: The one or more non-transitory computer-readable media of paragraph F, wherein: the first sensor is an image sensor, and the second sensor is one of: a lidar sensor, a time of flight sensor, a second image sensor, or a radar sensor.

H: The one or more non-transitory computer-readable media of paragraph F or G, the operations further comprising: determining a first feature of the environment based at least in part on the first view and a second feature of the environment based at least in part on the second view; and including the first feature and the second feature in the map.

I: The one or more non-transitory computer-readable media of paragraph H, wherein the machine learned model determines the first feature and the second feature at substantially a same time.

J: The one or more non-transitory computer-readable media of any of paragraphs F-I, where the machine learned model determines a first feature at a first time and a second feature at a second time after the first time, and the operations further comprising: determining a relationship between the first feature and the second feature; and including the relationship between the first feature and the second feature.

K: The one or more non-transitory computer-readable media of any of paragraphs F-J, wherein: the first view of the environment is a perspective view relative to the vehicle, and the second view of the environment is an elevation view relative to an area above the vehicle.

L: The one or more non-transitory computer-readable media of any of paragraphs F-K, wherein the machine learned model represents a decoder, and the operations further comprising: determining, by the decoder, an intermediate output based at least in part on a self-attention layer or a cross-attention layer; determining, by a first output head of the decoder and based at least in part on the intermediate output, a first feature of the map; and determining, by a second output head of the decoder and based at least in part on the intermediate output, a second feature of the map.

M: The one or more non-transitory computer-readable media of any of paragraphs F-L, wherein the machine learned model comprises a first model to determine a first feature and a second model to determine a second feature, and the operations further comprising: one of: determining the first feature by the first model and the second feature by the second model in parallel by a parallel processing unit, or determining the first feature by the first model at a first time and the second feature by the second model at a second time after the first time.

N: The one or more non-transitory computer-readable media of any of paragraphs F-M, wherein the map further comprises at least one of: a lane, a connection between two or more lanes, a boundary of the drivable surface, a curb, a crosswalk, a traffic indicator, a static object, the dynamic object, or road rules.

O: The one or more non-transitory computer-readable media of any of paragraphs F-N, inputting the first sensor data and the second sensor data into a perception component of a vehicle computing device of the vehicle; and receiving the third data from the perception component for input into the machine learned model.

P: The one or more non-transitory computer-readable media of any of paragraphs F-O, wherein: the first view includes a first range from the vehicle, the second view includes a second range from the vehicle, the second range is greater than the first range, and determining a feature of the map based at least in part on the second range being greater than the first range.

Q: A method comprising: determining, based at least in part on first sensor data associated with a first sensor of a vehicle, first data comprising a first view of an environment; determining, based at least in part on the first sensor data and second sensor data associated with a second sensor of the vehicle, second data comprising a second view of the environment, the second view different from the first view; receiving third data representing state data associated with a dynamic object detected in the environment at a previous time; inputting the first data, the second data, and the third data into a machine learned model; receiving, from the machine learned model, output data representing a map comprising a drivable surface that is defined at least in part on the first view of the first data and the second view of the second data; and controlling the vehicle in the environment based at least in part on the output data.

R: The method of paragraph Q, wherein: the first sensor is an image sensor, and the second sensor is one of: a lidar sensor, a time of flight sensor, another image sensor, or a radar sensor.

S: The method of paragraph Q or R, further comprising: determining a first feature of the environment based at least in part on the first view and a second feature of the environment based at least in part on the second view; and including the first feature and the second feature in the map.

T: The method of any of paragraphs Q-S, wherein the machine learned model represents a decoder, and the method further comprising: determining, by the decoder, an intermediate output based at least in part on a self-attention layer or a cross-attention layer; determining, by a first output head of the decoder and based at least in part on the intermediate output, a first feature of the map; and determining, by a second output head of the decoder and based at least in part on the intermediate output, a second feature of the map.

While the example clauses described below are described with respect to one particular implementation, it should be understood that, in the context of this document, the content of the example clauses can also be implemented via a method, device, system, computer-readable medium, and/or another implementation. Additionally, any of examples A-T may be implemented alone or in combination with any other one or more of the examples A-T.

### CONCLUSION

While one or more examples of the techniques described herein have been described, various alterations, additions, permutations and equivalents thereof are included within the scope of the techniques described herein.

In the description of examples, reference is made to the accompanying drawings that form a part hereof, which show by way of illustration specific examples of the claimed subject matter. It is to be understood that other examples can be used and that changes or alterations, such as structural changes, can be made. Such examples, changes or alterations are not necessarily departures from the scope with respect to the intended claimed subject matter. While the steps herein can be presented in a certain order, in some cases the ordering can be changed so that certain inputs are provided at different times or in a different order without changing the function of the systems and methods described. The disclosed procedures could also be executed in different orders. Additionally, various computations that are herein need not be performed in the order disclosed, and other examples using alternative orderings of the computations could be readily implemented. In addition to being reordered, the computations could also be decomposed into sub-computations with the same results.

1. A system comprising:
one or more processors; and
one or more non-transitory computer-readable media storing computer-executable instructions that, when executed, cause the one or more processors to perform operations comprising:
receiving, from a first sensor associated with an autonomous vehicle, first sensor data comprising a first view of an environment;
determining, based at least in part on the first sensor data and second sensor data from an additional sensor associated with the autonomous vehicle, image data comprising a second view of the environment, the second view different from the first view;
receiving historical data indicating one of:
state data associated with an object detected in the environment at a previous time;
region data representing a region of the environment; or
stored map data representing an area proximate the autonomous vehicle;
inputting the first sensor data comprising the first view, the image data comprising the second view, and the historical data into a machine learned model;
generating, by the machine learned model and based at least in part on the first sensor data, the image data, and the historical data, a map comprising features including a drivable surface or a non-drivable surface; and
controlling the autonomous vehicle in the environment based at least in part on the map.

2. The system of claim 1, wherein:
the first view of the environment is a perspective view relative to the autonomous vehicle,
the area is a first area;
the second view of the environment is an elevation view relative to a second area above the autonomous vehicle, and
the operations further comprising:
determining a first feature of the environment based at least in part on the perspective view and a second feature of the environment based at least in part on the elevation view; and
including the first feature and the second feature in the map.

3. The system of claim 1, wherein the machine learned model represents a decoder, and the operations further comprising:
determining, by the decoder, an intermediate output based at least in part on a self-attention layer or a cross-attention layer;
determining, by a first output head of the decoder and based at least in part on the intermediate output, a first feature of the map; and
determining, by a second output head of the decoder and based at least in part on the intermediate output, a second feature of the map.

4. The system of claim 1, wherein the machine learned model comprises a first model to determine a first feature of the features and a second model to determine a second feature of the features, and the operations further comprising one of:
determining the first feature by the first model and the second feature by the second model in parallel by a parallel processing unit; or
determining the first feature by the first model at a first time and the second feature by the second model at a second time after the first time.

5. The system of claim 1, wherein the map further comprises at least one of: a lane, a connection between two or more lanes, a boundary of the drivable surface, identification of a construction zone, a curb, a crosswalk, a traffic indicator, a static object, a dynamic object, or road rules for the autonomous vehicle and the object.

6. One or more non-transitory computer-readable media storing instructions executable by one or more processors, wherein the instructions, when executed, cause the one or more processors to perform operations comprising:
determining, based at least in part on first sensor data associated with a first sensor of a vehicle, first data comprising a first view of an environment;
determining, based at least in part on the first sensor data and second sensor data associated with a second sensor of the vehicle, second data comprising a second view of the environment, the second view different from the first view;
receiving state data associated with a dynamic object detected in the environment at a previous time;
inputting the first data, the second data, and the state data into a machine learned model;
receiving, from the machine learned model, output data representing a map comprising a drivable surface that is defined based at least in part on the first view of the first data and the second view of the second data; and
controlling the vehicle in the environment based at least in part on the output data.

7. The one or more non-transitory computer-readable media of claim 6, wherein:
the first sensor is an image sensor; and
the second sensor is one of: a lidar sensor, a time of flight sensor, a second image sensor, or a radar sensor.

8. The one or more non-transitory computer-readable media of claim 6, the operations further comprising:
determining a first feature of the environment based at least in part on the first view and a second feature of the environment based at least in part on the second view; and
including the first feature and the second feature in the map.

9. The one or more non-transitory computer-readable media of claim 8, wherein the machine learned model determines the first feature and the second feature at a same time.

10. The one or more non-transitory computer-readable media of claim 6, where the machine learned model determines a first feature at a first time and a second feature at a second time after the first time, and the operations further comprising:
determining a relationship between the first feature and the second feature; and
including the relationship between the first feature and the second feature.

11. The one or more non-transitory computer-readable media of claim 6, wherein:
the first view of the environment is a perspective view relative to the vehicle, and
the second view of the environment is an elevation view relative to an area above the vehicle.

12. The one or more non-transitory computer-readable media of claim 6, wherein the machine learned model represents a decoder, and the operations further comprising:
determining, by the decoder, an intermediate output based at least in part on a self-attention layer or a cross-attention layer;
determining, by a first output head of the decoder and based at least in part on the intermediate output, a first feature of the map; and
determining, by a second output head of the decoder and based at least in part on the intermediate output, a second feature of the map.

13. The one or more non-transitory computer-readable media of claim 6, wherein the machine learned model comprises a first model to determine a first feature and a second model to determine a second feature, and the operations further comprising one of:
determining the first feature by the first model and the second feature by the second model in parallel by a parallel processing unit; or
determining the first feature by the first model at a first time and the second feature by the second model at a second time after the first time.

14. The one or more non-transitory computer-readable media of claim 6, wherein the map further comprises at least one of: a lane, a connection between two or more lanes, a boundary of the drivable surface, a curb, a crosswalk, a traffic indicator, a static object, the dynamic object, or road rules.

15. The one or more non-transitory computer-readable media of claim 6,
inputting the first sensor data and the second sensor data into a perception component of a vehicle computing device of the vehicle; and
receiving the state third data from the perception component for input into the machine learned model.

16. The one or more non-transitory computer-readable media of claim 6, wherein:
the first view includes a first range from the vehicle,
the second view includes a second range from the vehicle,
the second range is greater than the first range, and
determining a feature of the map based at least in part on the second range being greater than the first range.

17. A method comprising:
determining, based at least in part on first sensor data associated with a first sensor of a vehicle, first data comprising a first view of an environment;
determining, based at least in part on the first sensor data and second sensor data associated with a second sensor of the vehicle, second data comprising a second view of the environment, the second view different from the first view;
receiving state data associated with a dynamic object detected in the environment at a previous time, the state data representing an orientation, a velocity, an acceleration, or a location of the dynamic object at the previous time;
inputting the first data, the second data, and the state data into a machine learned model;
receiving, from the machine learned model, a map comprising a drivable surface that is defined based at least in part on the first view of the first data and the second view of the second data; and
controlling the vehicle in the environment based at least in part on the map.

18. The method of claim 17, wherein:
the first sensor is an image sensor; and
the second sensor is one of: a lidar sensor, a time of flight sensor, another image sensor, or a radar sensor.

19. The method of claim 17, further comprising:
determining a first feature of the environment based at least in part on the first view and a second feature of the environment based at least in part on the second view; and
including the first feature and the second feature in the map.

20. The method of claim 17, wherein the machine learned model represents a decoder, and the method further comprising:
determining, by the decoder, an intermediate output based at least in part on a self-attention layer or a cross-attention layer;
determining, by a first output head of the decoder and based at least in part on the intermediate output, a first feature of the map; and
determining, by a second output head of the decoder and based at least in part on the intermediate output, a second feature of the map.
